(19) United States
(12) Patent Application Publication
(10) Pub. No.: US 2026/0146365 A1
(43) Pub. Date: May 28, 2026

(54) COOLING ARRANGEMENTS FOR PROCESSING SYSTEMS, CHAMBERS, AND RELATED METHODS TO MODIFY SUBSTRATE TEMPERATURE PROFILES

(71) Applicant: Applied Materials, Inc., Santa Clara, CA (US)

(72) Inventor: Abbas RASTEGAR, Schenectady, NY (US)

(21) Appl. No.: 18/960,809

(22) Filed: Nov. 26, 2024

(51) Int. Cl. C30B 25/10; C23C 16/458; C23C 16/46; C30B 25/12; C30B 25/16

(52) U.S. Cl. CPC C30B 25/10; C23C 16/4583; C23C 16/463; C30B 25/12; C30B 25/16

(57) ABSTRACT

A processing system applicable for use in semiconductor manufacturing, including a chamber. The chamber including a chamber body at least partially defining an internal volume, one or more windows disposed in the internal volume, a substrate support at least partially disposed in the internal volume, one or more heat sources operable to heat the internal volume, and one or more cooling channels. The one or more cooling channels extend at least partially between the one or more heat sources and the one or more windows. The one or more cooling channels are operable to flow a cooling fluid.

### BACKGROUND

### Field

Embodiments of the present disclosure generally relate to chambers, methods, systems, and related components for modifying temperature profiles in relation to substrate processing for semiconductor manufacturing.

### Description of the Related Art

Semiconductor substrates are processed for a wide variety of applications, including the fabrication of integrated devices and microdevices. Substrates can undergo a variety of processing operations, which can involve high temperature operations. As an example, substrates can experience heating from heating devices within processing chambers. The radiation from these heating devices may not be uniform which can lead to nonuniform temperature profiles experienced by the substrates. The nonuniform temperature profiles can lead to nonuniform growth of layers on the substrates, such as epitaxial layers.

Therefore, a need exists for chambers, systems, and methods that facilitate modifying temperature profiles of substrates.

### SUMMARY

Embodiments of the present disclosure relate to chambers, methods, systems, and related components for modifying substrate temperature profiles in relation to substrate processing for semiconductor manufacturing.

In one or more embodiments, a processing system applicable for use in semiconductor manufacturing, including a chamber. The chamber including a chamber body at least partially defining an internal volume, one or more windows disposed in the internal volume, a substrate support at least partially disposed in the internal volume, one or more heat sources operable to heat the internal volume, and one or more cooling channels. The one or more cooling channels extend at least partially between the one or more heat sources and the one or more windows. The one or more cooling channels are operable to flow a cooling fluid.

In one or more embodiments, a processing system applicable for use in semiconductor manufacturing, including a chamber. The chamber including a chamber body at least partially defining an internal volume, a substrate support at least partially disposed in the internal volume, one or more heat sources operable to heat the internal volume, and one or more blocker plates disposed between the one or more heat sources and the substrate support.

In one or more embodiments, method of substrate processing for semiconductor processing, including heating a substrate positioned in a processing volume of a chamber using one or more heat sources, absorbing and/or reflecting a portion of the heat to reduce the heat supplied to a portion of the substrate, and flowing one or more processing gases over the substrate to form one or more layers of the substrate.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram top plan view of a processing system, according to one or more embodiments.

FIG. 2A is a partial schematic side cross-sectional view of a processing system including a processing chamber, according to one or more embodiments.

FIG. 2B is a schematic top view of a substrate with a non-uniform temperature profile, according to one or more embodiments.

FIG. 2C is a schematic top view of a cooling channel, according to one or more embodiments.

FIG. 2D illustrate charts of temperature profiles of a substrate with a non-uniform temperature profile, a cooling temperature profile, and a modified temperature profile of the substrate, according to one or more embodiments.

FIG. 3A is a partial schematic side cross-sectional view of a processing system including a processing chamber, according to one or more embodiments.

FIG. 3B is a schematic top view of a substrate with a non-uniform temperature profile, according to one or more embodiments.

FIG. 3C is a schematic top view of a cooling channel, according to one or more embodiments.

FIG. 3D illustrate charts of temperature profiles of a substrate with a non-uniform temperature profile, a cooling temperature profile, and a modified temperature profile of the substrate, according to one or more embodiments.

FIG. 4A is a partial schematic side cross-sectional view of a processing system including a processing chamber, according to one or more embodiments.

FIG. 4B is a schematic top view of a substrate with a non-uniform temperature profile, according to one or more embodiments.

FIG. 4C is a schematic top view of a blocker plate, according to one or more embodiments.

FIG. 4D illustrate charts of temperature profiles of a substrate with a non-uniform temperature profile, a cooling temperature profile, and a modified temperature profile of the substrate, according to one or more embodiments.

FIG. 5 illustrates a method for modifying the temperature profile of a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to chambers, methods, systems, and related components for modifying temperature profiles in relation to substrate processing for semiconductor manufacturing.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

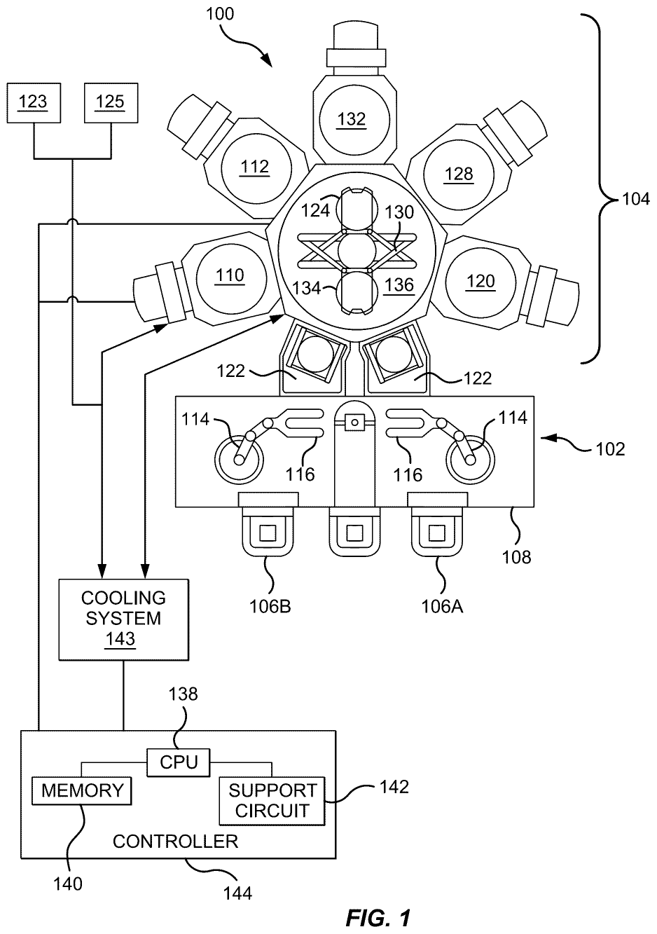

FIG. 1 is a schematic diagram top plan view of a processing system 100, according to one or more embodiments. The processing system 100 includes one or more substrate load lock chambers 122, a vacuum-tight processing platform 104, a factory interface 102, and a controller 144. The processing system 100 includes subfab support equipment 123 (e.g., a pump, abatement equipment, a scrubber, a heat exchanger, and/or a chiller), a cooling system 143, and reactor support modules 125 (e.g., a gas panel, an AC box, controller(s), and/or a facility tray). The controller 144 can be part of the reactor support modules 125. The substrate load lock chambers 122 may be load lock chambers. In one or more embodiments, the processing system 100 may be a CENTURA® integrated processing system, commercially available from Applied Materials, Inc., located in Santa Clara, California. It is contemplated that other processing systems (including those from other manufacturers) may be adapted to benefit from the disclosure.

The platform 104 includes a plurality of processing chambers 110, 112, 128, 120, 132 and the one or more substrate load lock chambers 122 that are coupled to a vacuum substrate transfer chamber 136. In one or more embodiments, the processing chambers 110, 112, 128, 120, 132 include heat sources and heat sinks. Two substrate load lock chambers 122 are shown in FIG. 1. The factory interface 102 is coupled to the transfer chamber 136 through the substrate load lock chambers 122.

A cooling system 143 is electrically connected to one or more of the controller 144, the processing system 100 (such as parts, for example the transfer chamber 136, of the processing platform 104), the subfab support equipment 123, the reactor support modules 125, and/or one or more of the processing chambers 110, 112, 128, 120, 132 for power supply. In one or more embodiments, the cooling system 143, subfab support equipment 123, and/or reactor support modules 125 are mounted to the processing platform 104. It is also contemplated that cooling system 143, subfab support equipment 123, and/or reactor support modules 125 may be offset from the processing platform 104 (e.g. off-board of the processing platform 104). In one or more embodiments, the cooling system 143 includes one or more mass flow controllers, pressure control valves, reservoirs, and/or actuators. The cooling system 143 may be controlled by the controller 144.

In one or more embodiments, the factory interface 102 includes at least one docking station 108 and at least one factory interface robot 114 to facilitate the transfer of substrates. The docking station 108 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the substrate load lock chambers 122, and to the processing platform 104 for processing. Substrates being transferred can be stored at least temporarily in the substrate load lock chambers 122.

Each of the substrate load lock chambers 122 has a first port interfacing with the factory interface 102 and a second port interfacing with the transfer chamber 136. The substrate load lock chambers 122 are coupled to a pressure control system which pumps down and vents the substrate load lock chambers 122 to facilitate passing the substrates between the vacuum environment of the transfer chamber 136 and a substantially ambient (e.g., atmospheric) environment of the factory interface 102.

The transfer chamber 136 has a vacuum robot 130 disposed therein. The vacuum robot 130 has a blade 134 capable of transferring the substrates 124 between the substrate load lock chambers 122 and the processing chambers 110, 112, 132, 128, 120.

The controller 144 (e.g. control system) is communicatively coupled to the processing system 100. The controller 144 controls the operations of the system 100 using a direct control of the process chambers 110, 112, 132, 128, 120 of the system 100 or alternatively, by controlling the computers (or controllers) associated with the process chambers 110, 112, 128, 120, 132 and the system 100. In operation, the controller 144 enables data collection and feedback from the respective chambers and controller 144 to optimize performance of the system 100.

The controller 144 is used to control processes and methods, such as the operations of the methods described herein (for example the operations of the method 500 described below). The controller 144 includes a central processing unit (CPU) 138, a memory 140 containing instructions, and support circuits 142 for the CPU. The controller 144 controls various items directly, or via other computers and/or controllers. In one or more embodiments, the controller 144 is communicatively coupled to dedicated controllers and the controller 144 functions as a central controller.

The controller 144 is of any form of a general-purpose computer processor that is used in an industrial setting for controlling various substrate processing chambers and equipment, and sub-processors thereon or therein. The memory 140, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 142 of the controller 144 are coupled to the CPU 138 for supporting the CPU 138 (a processor). The support circuits 142 can include cache, power supplies, clock circuits, input/output circuitry and subsystems, and the like. Operational parameters (such as process gas concentration, process gas flow rate, heating power for processing temperature, substrate support rotation speed, cooling fluid flow rate, cooling fluid temperature, and/or other process recipe parameter(s)) and operations are stored in the memory 140 as software routine(s) that are executed or invoked to turn the controller 144 into a specific purpose controller to control the operations of the various systems/chambers/units/modules described herein. The software routine(s), when executed by the CPU 138, transform the CPU 138 into a specific purpose computer. The software routines may also be stored and/or executed by a second controller (not shown) that is located remotely from the system 100.

The controller 144 is configured to conduct any of the operations described herein. The instructions stored on the memory, when executed, cause one or more of operations of method 500 (described below) to be conducted.

The various operations described herein can be conducted automatically using the controller 144, or can be conducted automatically and/or manually with certain operations conducted by a user.

The controller 144 is configured to adjust output to controls of the system 100 based off of sensor readings, a system model, and stored readings and calculations. As an example, one or more operating parameters can be measured by one or more sensors positioned along the system 100. The controller 144 includes embedded software and a compensation algorithm to calibrate measurements. The controller 144 can include one or more machine learning algorithms and/or artificial intelligence algorithms that estimate optimized parameters for deposition operation(s), cleaning operations, etching operations, and/or atomic radical treatment operation(s). The one or more machine learning algorithms and/or artificial intelligence algorithms can use, for example, a regression model (such as a linear regression model) or a clustering technique to estimate optimized parameters. The algorithm can be unsupervised or supervised.

The one or more machine learning algorithms and/or artificial intelligence algorithms can optimize the operating parameters used in relation to operations described herein. In one or more embodiments, the one or more machine learning algorithms and/or artificial intelligence algorithms learn power usage throughout processing operations and optimize parameters to reduce energy usage while maintaining or enhanced processing efficacy. In one or more embodiments, the one or more machine learning algorithms and/or artificial intelligence algorithms optimize processing power and/or process recipe parameter(s).

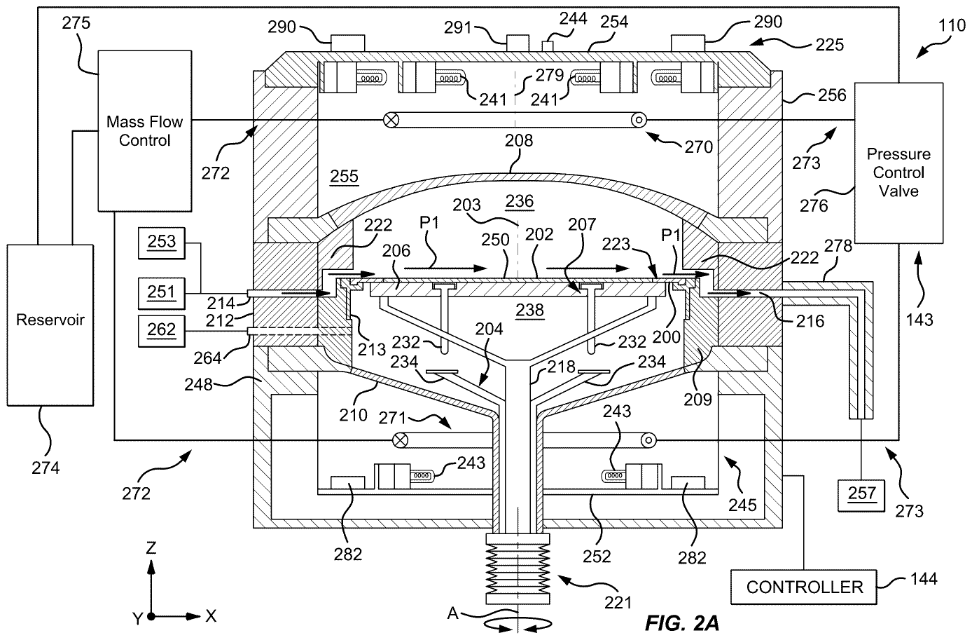

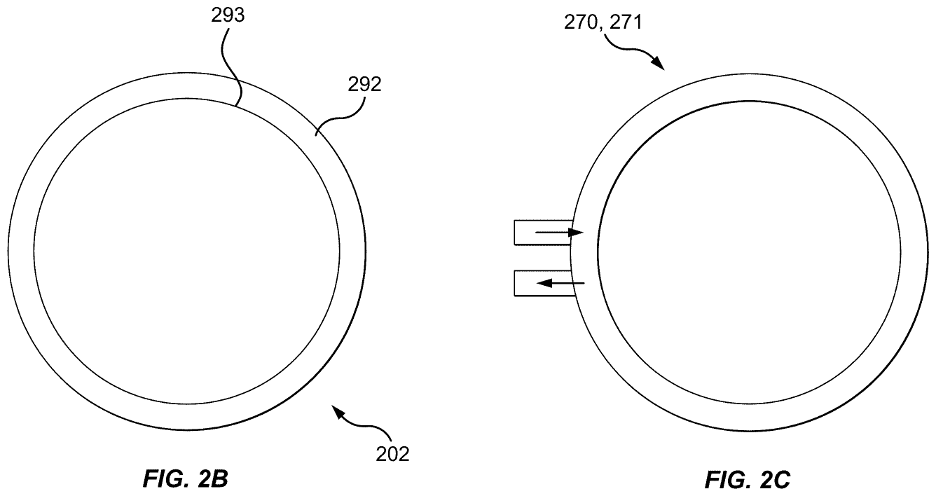

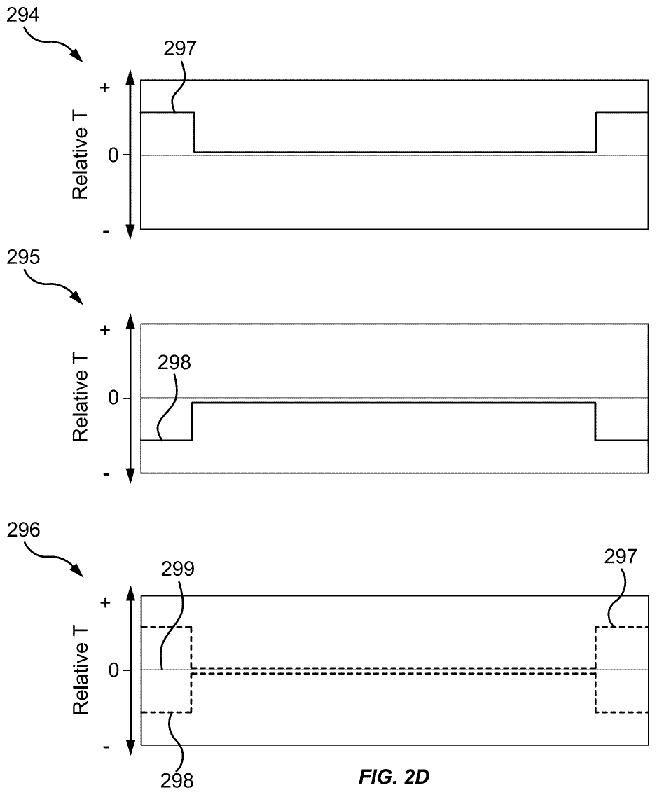

FIG. 2A is a partial schematic side cross-sectional view of a processing system including a processing chamber, such as processing chamber 110 shown in FIG. 1, according to one or more embodiments. The processing chamber 110 is a deposition chamber. In one or more embodiments, the processing chamber 110 is an epitaxial deposition chamber. The processing chamber 110 is utilized to grow an epitaxial film on a substrate 202. The processing chamber 110 creates a cross-flow of precursors across a top surface 250 of the substrate 202. In one or more embodiments, the process chamber 110 includes a reactor portion 225.

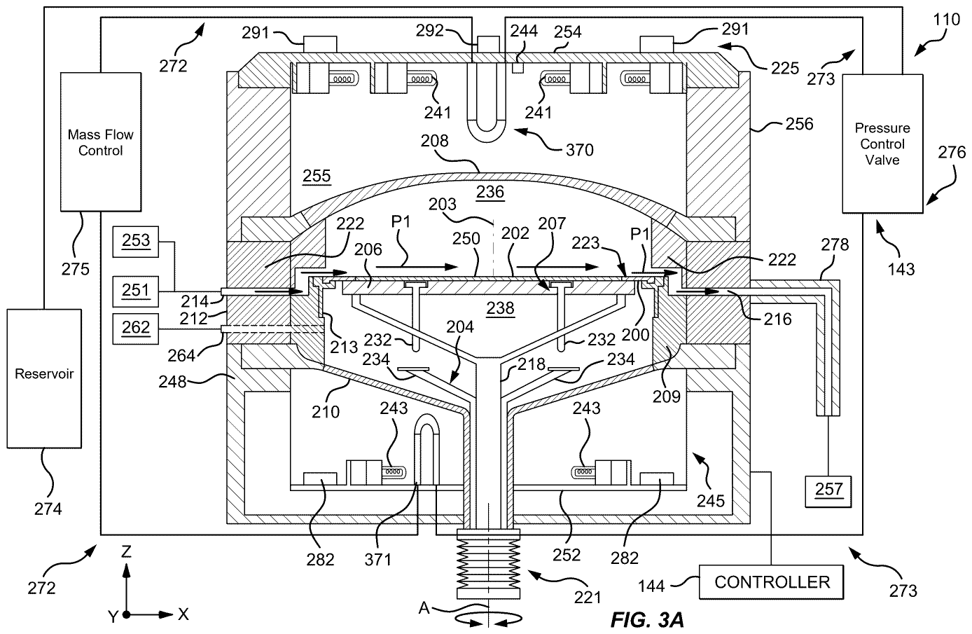

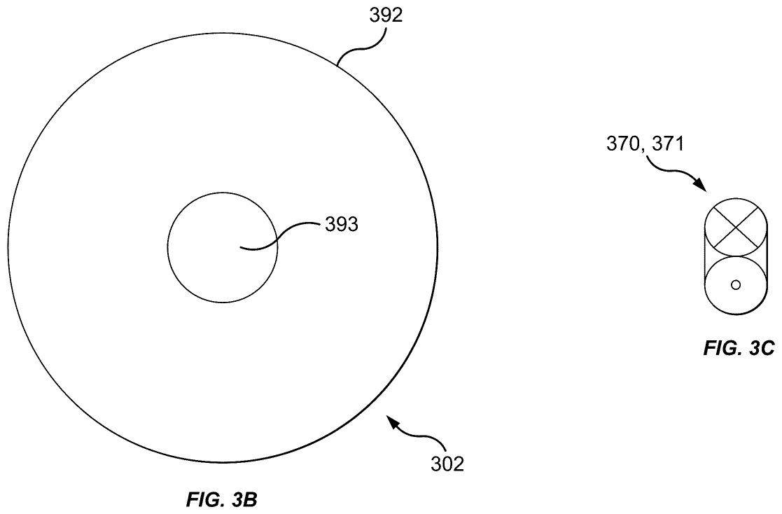

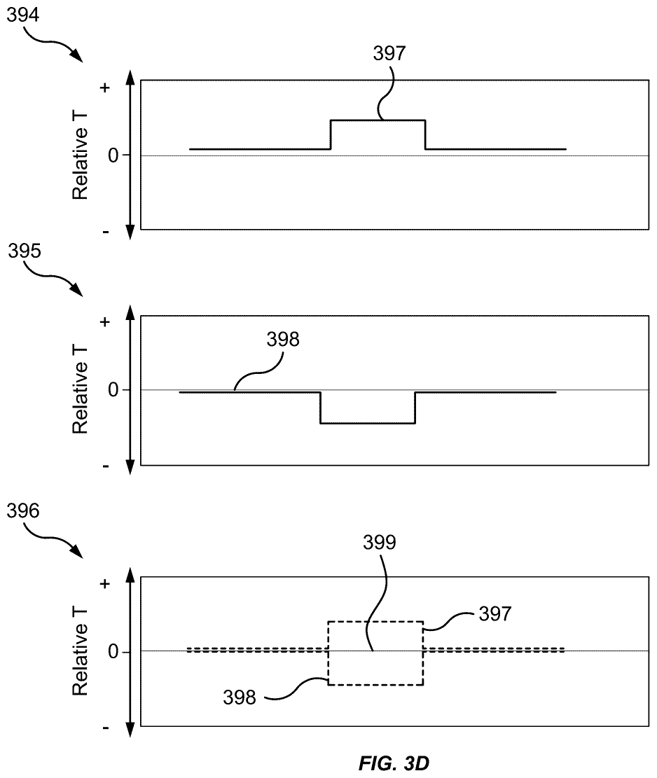

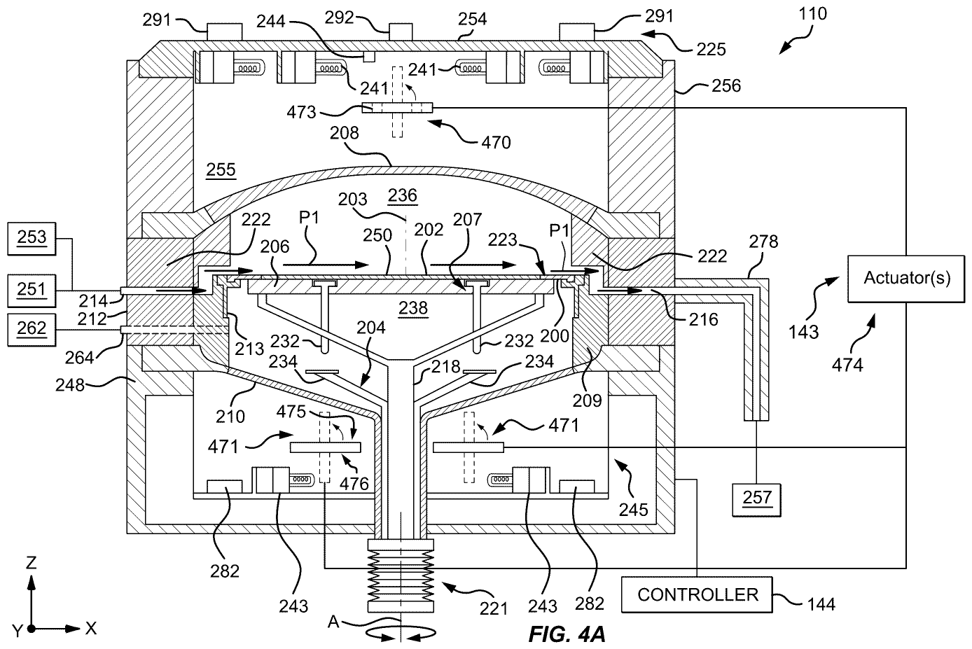

The processing chamber 110 includes an upper body 256, a lower body 248 disposed below the upper body 256, and a flow module 212 disposed between the upper body 256 and the lower body 248. The upper body 256, the flow module 212, and the lower body 248 form at least part of a chamber body. The chamber body at least partially defines an internal volume. Disposed within the internal volume is a substrate support 206, an upper window 208 (such as an upper dome), a lower window 210 (such as a lower dome), a plurality of upper heat sources 241, a plurality of lower heat sources 243, one or more targeted heaters 244, one or more upper cooling channels 270 and one or more lower cooling channels 271. The one or more targeted heaters 244 can be one or more spot heaters, such as one or more laser heaters. The one or more targeted heaters 244 can be disposed outwardly of the lid 254 (as shown in FIG. 2A) or inwardly of the lid 254 (as shown in FIG. 3A). The present disclosure contemplates that other structures may be used in place of the upper window 208 and/or the lower window 210. For example, a flat plate and/or an opaque plate may be used in place of the upper window 208 and/or the lower window 210. The present disclosure contemplates that a variety of plate structures shapes and profiles can be used for the upper window 208 and/or the lower window 210. As shown, a controller 144 is in communication with the processing chamber 110 and is used to control processes and methods, such as the operations of the methods described herein.

In the implementation shown in FIG. 2, the heat sources 241, 243 are lamps operable to heat the internal volume of the chamber 110. Other heat sources are contemplated, such as resistive heaters, light emitting diodes (LEDs), and/or lasers. For example, the one or more spot heaters 244 may be configured to heat targeted areas of the substrate 202 by methods including, but not limited to, lasers. In one or more embodiments, the heat sources 241, 243 emit heat to increase the temperature of substrate 202 for substrate processing, such as for epitaxial deposition. In one or more embodiments, the heat sources 241, 243 emit infrared (IR) energy (such as radiation) to heat the substrate 202. The present disclosure contemplates that heat sources may be used that emit energy other than IR energy, such as ultraviolet energy and/or microwave energy.

The cooling channels 270, 271 are disposed to extend at least partially between the heat sources 241, 243 and the substrate support 206. In one or more embodiments, the one or more upper cooling channels 270 are disposed below the upper heat sources 241 and above the substrate 202, and the one or more lower cooling channels 271 are disposed above the lower heat sources 243 and below the substrate 202.

In one or more embodiments, the one or more upper cooling channels 270 are disposed above the upper window 208. In one or more embodiments, the one or more upper cooling channels 270 are disposed below the upper window 208. In one or more embodiments, the one or more lower cooling channels 271 are disposed below the lower window 210. In one or more embodiments, the one or more lower cooling channels 271 are disposed above the lower window 210.

In one or more embodiments, the cooling channels 270, 271 are tubular (such as glass tubes) and are configured to receive heat absorbing fluid from supply lines 272, flow said fluid, and supply said fluid to return lines 273. The cooling channels are formed of an energy transmissive material, such as quartz, (e.g., transparent quartz, such as fused silica glass).

The heat transmitted from the heat sources 241, 243 is at least partially absorbed by the heat-absorbing fluid in the cooling channels 270, 271 thus creating a cooling profile in the shape of the cooling channels 270, 271. Accordingly, the temperature profile of the substrate 202 may be modified by the cooling channels 270, 271. In one or more embodiments, the heat emitted by the heat sources 241, 243 is from infrared (IR) energy. Accordingly, the heat absorbing fluid may be IR absorbing fluid.

The heat absorbing fluid is supplied to the cooling channels 270, 271 by supply lines 272. The supply lines 272 are fluidly coupled to the cooling system 143. In one or more embodiments, such as the illustrated embodiment, the cooling system 143 includes a reservoir 274, a mass flow control 275, and pressure control valve 276. The heat absorbing fluid is stored in the reservoir 274. The mass flow control 275 is configured to flow, and control the flow of, the heat absorbing fluid through the cooling channels 270, 271. The pressure control valve 276 is configured to control the pressure and flow of the heat absorbing fluid through the cooling channels 270, 271 before the heat absorbing fluid is returned to the reservoir 274. Accordingly, the heat absorbing fluid is flowed from the reservoir 274, through the mass flow control 275, through the cooling channels 270, 271, through the pressure control valve 276, and back into the reservoir 274.

The heat absorbing fluid may be any fluid that absorbs heat (e.g., IR). The amount of absorption is determined by the heat absorbing fluid properties (such as composition and/or density) and by the flow rates and pressures of the heat absorbing fluid flowing through the cooling channels 270, 271. Accordingly, the amount of absorption may be controlled by controlling the composition and flow properties of the heat absorbing fluid. In one or more embodiments, the heat absorbing fluid includes a heat absorbing gas or vapor. In one or more embodiments, a heat absorbing gas may include water vapor. In one or more embodiments, the water vapor is manipulated to control heat absorption. In one or more embodiments, the water vapor may be saturated to form nano-and microdroplets by adjusting pressure and flow rate of the water vapor. The heat absorption of the saturated water vapor may be dependent on size of the droplets. In one or more embodiments, the water vapor is mixed with carbon dioxide gas. In one or more embodiments, nanoparticles are added to water vapor to increase the heat absorption. For example, silicon nitride nanoparticles can be added to the water vapor to increase heat absorption. The absorption properties of such heat absorbing fluids is determined by the particle size and material. In one or more embodiments, molecular dye is added to the water vapor that may partially or completely absorb heat.

The shape of the cooling channels 270, 271 determines the portion of the heat absorbed. Thus, the shape of the cooling channels 270, 271 determines the cooling profile. The cooling channels 270, 271 may be any shape so long as the heat absorbing fluid is allowed to flow through the cooling channels 270, 271 and so long as the cooling channels 270, 271 are positioned within the chamber 110 in a way to absorb at least a portion of the heat from the heat sources 241, 243. In one or more embodiments, the cooling channels 270, 271 may be a part of one or more loops (e.g., cooling loops). The channels 270, 271 may similarly be shaped in any way so long as the heat absorbing fluid is allowed to flow through the cooling channels 270, 271 and so long as the cooling channels 270, 271 are positioned within the chamber 110 in a way to absorb at least a portion of the heat from the heat sources 241, 243. For example, as illustrated in FIG. 2A, the cooling channels 270, 271 may be circular loops (e.g., cooling loops) with a central axis 279 that is coaxial or parallel with the central axis 203 of the substrate 202 and substrate support 206. In one or more embodiments, the central axis 279 is offset (such as angularly offset and/or laterally offset) from the central axis 203 of the substrate 202.

While the presently illustrated embodiment includes one upper cooling channel 270 and one lower cooling channel 271, it is understood that there may be any number of cooling channel 270, 271 which may be upper cooling channels 270 or which may be lower cooling channels 271, which may be similarly shaped or differently shaped, and which may be similarly positioned or differently positioned. In one or more embodiments, the upper cooling channels 270 are omitted, and in one or more embodiments the lower cooling channels 271 are omitted.

The processing chamber 110 may include one or more sensors 290, 291, 282, such as temperature sensors (e.g., optical pyrometers) or other metrology sensors, which measure temperatures (or other parameters) within the processing chamber 110 (such as on the surfaces of the upper window 208, surfaces of the lower window 210, and/or one or more surfaces of the substrate 202 and/or the substrate support 206). The one or more sensors 290, 291 are disposed on the lid 254. The one or more sensors 282 (e.g., lower pyrometers) are disposed on or adjacent to a floor 252. The one or more sensors 282 can be disposed on the lower side of the lower window 210.

The substrate support 206 is disposed between the upper window 208 and the lower window 210. The substrate support 206 includes a support face 223 that supports the substrate 202. The plurality of upper heat sources 241 are disposed between the upper window and a lid 254. The plurality of upper heat sources 241 form a portion of the upper heat source module 255. The plurality of lower heat sources 243 are disposed between the lower window 210 and the floor 252. The plurality of lower heat sources 243 form a portion of a lower heat source module 245. The upper window 208 and the lower window 210 are formed of an energy transmissive material, such as quartz (e.g., transparent quartz).

A process volume 236 and a purge volume 238 are formed between the upper window 208 and the lower window 210. The process volume 236 and the purge volume 238 are part of an internal volume defined at least partially by the upper window 208, the lower window 210, an upper liner 222, and one or more lower liners 209. In one or more embodiments, the one or more lower liners 209 include an inner liner 213.

The internal volume has the substrate support 206 disposed therein. The substrate support 206 includes a top surface on which the substrate 202 is disposed. The substrate support 206 is attached to a shaft 218. The shaft 218 is connected to a motion assembly 221. The motion assembly 221 includes one or more actuators and/or adjustment devices that provide movement and/or adjustment for the shaft 218 and/or the substrate support 206 within the processing volume 236.

The substrate support 206 may include lift pin holes 207 disposed therein. The lift pin holes 207 are sized to accommodate lift pins 232 for lowering and lifting of the substrate 202 to and from the substrate support 206 before and after a deposition process is conducted. The lift pins 232 may rest on lift pin stops 234 when the substrate support 206 is lowered from a process position to a transfer position. The lift pin stops 234 can be coupled to a second shaft 204 through a plurality of arms.

The flow module 212 includes a plurality of gas inlets 214, a plurality of purge gas inlets 264, and one or more gas exhaust outlets 216. In one or more embodiments, the plurality of gas inlets 214 and the plurality of purge gas inlets 264 are disposed on the opposite side of the flow module 212 from the one or more gas exhaust outlets 216. The upper liner 222 and the one or more lower liners 209 are disposed on inner surface(s) of the flow module 212 and protect the flow module 212 from reactive gases used during deposition operations and/or cleaning operations. The gas inlet(s) 214 and the purge gas inlet(s) 264 are each positioned to flow a gas parallel to the top surface 250 of the substrate 202 disposed within the process volume 236. The gas inlet(s) 214 are fluidly connected to one or more process gas sources 251 and one or more cleaning gas sources 253. The purge gas inlet(s) 264 are fluidly connected to one or more purge gas sources 262. The one or more gas exhaust outlets 216 are fluidly connected to an exhaust pump 257. One or more process gases supplied using the one or more process gas sources 251 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 262 can include one or more inert gases (such as one or more of argon (Ar), helium (He), hydrogen (H₂), and/or nitrogen (N₂)). One or more cleaning gases supplied using the one or more cleaning gas sources 253 can include one or more of hydrogen (H) and/or chlorine (Cl). In one or more embodiments, the one or more process gases include silicon phosphide (SiP) and/or phospine (PH₃), and the one or more cleaning gases include hydrochloric acid (HCl).

The one or more gas exhaust outlets 216 are further connected to or include an exhaust system 278. The exhaust system 278 fluidly connects the one or more gas exhaust outlets 216 and the exhaust pump 257. The exhaust system 278 can assist in the controlled deposition of a layer on the substrate 202. In one or more embodiments, the exhaust system 278 is disposed on an opposite side of the processing chamber 110 relative to the gas inlet(s) 214 and/or the purge gas inlets 264.

A pre-heat ring 200 is disposed outwardly of the substrate support 206. In one or more embodiments, the pre-heat ring 200 is supported on a ledge of the inner liner 213. In one or more embodiments, the pre-heat ring 200 is formed of one or more of quartz (such as a transparent quartz—e.g. clear quartz, and/or opaque quartz—e.g. white quartz, grey quartz, and/or black quartz), silicon carbide (SiC), and/or graphite coated with SiC.

In one or more embodiments, the liners 209, 213, and/or 222 are formed of one or more of quartz (such as transparent quartz—e.g. clear quartz, and/or opaque quartz—e.g. white quartz, grey quartz, and/or black quartz), silicon carbide (SiC), and/or graphite coated with SiC.

In the implementation shown in FIG. 2, the inner liner 213 and the pre-heat ring 200 are separate bodies. In one or more embodiments, the pre-heat ring 200 and the inner liner 213 are integrally formed as a monolithic body. In the implementation shown in FIG. 2, the inner liner 213 and the lower liner 209 are separate bodies. In one or more embodiments, the lower liner 209 and the inner liner 213 are integrally formed as a monolithic body.

One or more process gases P1 flow from the gas inlet(s) 214, into the processing volume 236, and over the substrate 202 to form (e.g., epitaxially grow) one or more layers on the substrate 202 while the heat sources 241, 243 heat the pre-heat ring 200, the substrate support 206, and/or the substrate 202. After flowing over the substrate 202, the one or more process gases P1 flow out of the internal volume through the one or more gas exhaust outlets 216. The flow module 212 can be at least part of a sidewall of the processing chamber 110. The present disclosure also contemplates that one or more purge gases can be supplied to the purge volume 238 (e.g., through the plurality of purge gas inlets 264) during the deposition operation, and exhausted from the purge volume 238.

FIG. 2B illustrates a schematic top view of a substrate 202 with a non-uniform temperature profile. In the implementation illustrated in FIG. 2B, the temperature of perimeter 292 of the substrate 202 is higher than the temperature at the center 293. FIG. 2C illustrates a schematic top view of one of the cooling channels 270, 271 of FIG. 2A that may be used to generate a cooling profile complementary to the non-uniform temperature profile of the substrate 202 of FIG. 2B to make the resulting temperature profile uniform. FIG. 2D includes a chart 294 illustrating the non-uniform temperature profile 297 of the substrate 202 of FIG. 2B, a chart 295 illustrating the cooling profile 298 generated by the cooling channels 270,271 of FIG. 2C, and chart 296 illustrates the resulting temperature profile 299 of the substrate 202 of FIG. 2B due to the use of the cooling channel 270,271 of FIG. 2C.

As shown in chart 294 of FIG. 2D, the substrate 202 may have a temperature profile 297 with a higher temperature at the perimeter 292 of the substrate 202 than the temperature at the center 293 of the substrate 202. As shown in chart 295 of FIG. 2D, the cooling channel 270, 271 and heat absorbing fluid of FIG. 2C may be designed (e.g., through the manipulation of heat absorbing fluid composition, through the manipulation of heat absorbing flow characteristics, and through the manipulation of the shape of the cooling channel) to have a complementary temperature profile 298 to the non-uniform temperature profile of the substrate 202 of FIG. 2B (e.g., a cooling profile 298). As shown in chart 296 of FIG. 2D, the cooling profile 298 of the cooling channel 270, 271 and heat absorbing fluid may be used to make the resulting temperature profile 299 of the substrate 202 uniform.

FIG. 3A is a partial schematic side cross-sectional view of a processing system including a processing chamber, such as the processing chamber 110 of FIG. 1.

The processing system shown in FIG. 3A is similar to the processing system shown in FIG. 2A, and includes one or more features, aspects, components, operations, and/or properties thereof. For the sake of brevity, components in FIG. 3A that operate similarly to those in FIG. 2A have been given the same reference numbers and a description of such components will not be repeated herein

As previously described with respect to FIG. 2A, the shape of the cooling channels 270, 271 determines the portion of the heat absorbed and determines the cooling profile. Accordingly, in FIG. 3A, the cooling channels 370, 371 are U-shaped loops extending from the walls of the chamber 110. In one or more embodiments, the one or more upper cooling channels 370 are U-shaped loops extending down from the top wall of the chamber 110 such that an inlet section (e.g., inlet tube) of the U-shape and an outlet section (e.g., outlet tube) of the U-shape are parallel to the central axis 203 of the substrate support 206 and the substrate 202. In one or more embodiments, the one or more lower cooling channels 371 are U-shaped loops extending up from the bottom wall of the chamber 110 such that an inlet section (e.g., inlet tube) of the U-shape and an outlet section (e.g., outlet tube) of the U-shape are parallel to the central axis 203 of the substrate support 206 and the substrate 202. The present disclosure also contemplates that the one or more lower cooling channels 371 can be in the shape of a tube oriented as an arc (such as a circle) oriented in a horizontal plane—as shown for the one or more cooling channels 271 in FIG. 2A. The U-shaped loops may be located at or near (e.g., vertically aligned with) the central axis 203 of the substrate 202 and substrate support 206, may be located at or near (e.g., vertically aligned with) an edge of the substrate 202 and substrate support 206, or anywhere therebetween.

While FIGS. 2A and 3A only illustrate the cooling channels as circular and U-shaped, it is understood that the cooling channels may be any shape so that the cooling profile generated by the cooling channels is complementary to the non-uniform temperature profile of a substrate.

FIG. 3B illustrates a schematic top view of a substrate 302 with a non-uniform temperature profile. In the embodiment illustrated in FIG. 3B, the temperature of the center 393 of the substrate 302 is higher than the temperature at the perimeter 392. FIG. 3C illustrates a schematic top view of one of the cooling channels 370, 371 of FIG. 3A that may be used to generate a cooling profile complementary to the non-uniform temperature profile of the substrate 302 of FIG. 3B to make the resulting temperature profile uniform. FIG. 2D includes a chart 394 illustrating the non-uniform temperature profile 397 of the substrate of FIG. 3B, a chart 395 illustrating the cooling profile 398 generated by the cooling channel 370, 371 of FIG. 3C, and chart 396 illustrates the resulting temperature profile 399 of the substrate 302 of FIG. 3B due to the use of the cooling channel 370, 371 of FIG. 3C.

As shown in chart 394 of FIG. 3D, the substrate 302 may have a temperature profile 397 with a higher temperature at the center 393 of the substrate 302 than the temperature at the perimeter 392 of the substrate 302. As shown in chart 395 of FIG. 3D, the cooling channel 370, 371 and heat absorbing fluid of FIG. 3C may be designed (e.g., through the manipulation of heat absorbing fluid composition, through the manipulation of heat absorbing flow characteristics, and through the manipulation of the shape of the cooling channel) to have a complementary temperature profile 398 to the non-uniform temperature profile of the substrate 302 of FIG. 2B (e.g., a cooling profile 398). As shown in chart 396 of FIG. 3D, the cooling profile 398 of the cooling channel 370, 371 and heat absorbing fluid may be used to make the resulting temperature profile 399 of the substrate 302 uniform.

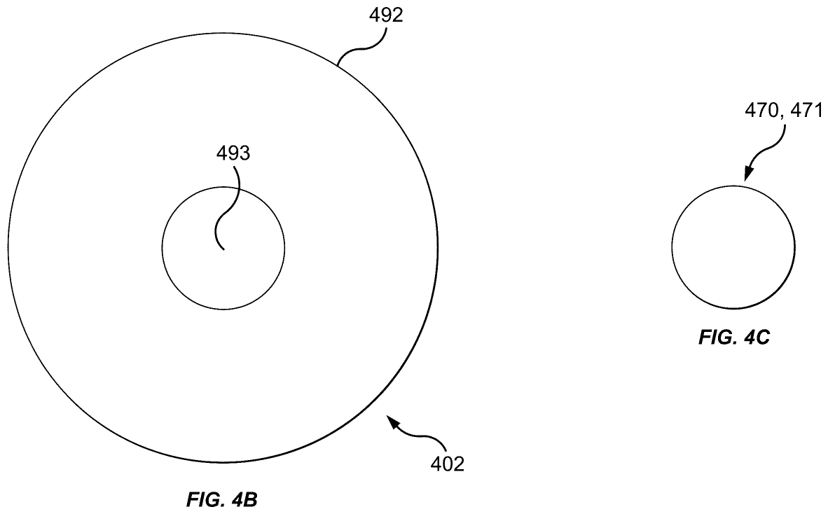

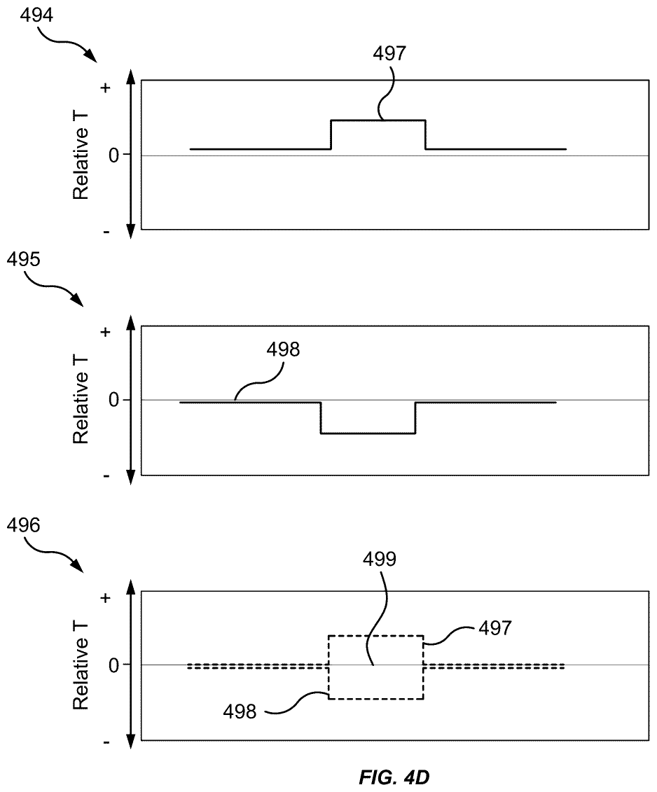

FIG. 4A is a partial schematic side cross-sectional view of a processing system including a processing chamber, such as the processing chamber 110 of FIG. 1.

The processing system shown in FIG. 4A is similar to the processing system shown in FIGS. 2A and 3A, and includes one or more features, aspects, components, operations, and/or properties thereof. For the sake of brevity, components in FIG. 4A that operate similarly to those in FIGS. 2A and 3A have been given the same reference numbers and a description of such components will not be repeated herein.

Rather than cooling channels (such as cooling channels 370, 371, 370, 371 of FIGS. 2A and 3A), the processing chamber 110 of FIG. 4A includes one or more upper blocker plates 470 and one or more lower blocker plates 471 to modify the temperature profile of the substrate 202 by absorbing and/or reflecting the heat from the heat sources 241, 243. The blocker plates 470, 471 are disposed between the heat sources 241, 243 and the substrate support 206. For instance, the one or more upper blocker plates 470 are disposed below the upper heat sources 241 and above the substrate 202 and the one or more lower blocker plates are disposed above the lower heat sources 243 and below the substrate 202.

In one or more embodiments, the one or more upper blocker plates 470 are disposed above the upper window 208. In one or more embodiments, the one or more upper blocker plates 470 are disposed below the upper window 208. In one or more embodiments, the one or more lower blocker plates 471 are disposed below the lower window 210. In one or more embodiments, the one or more lower blocker plates 471 are disposed above the lower window 210. In one or more embodiments, the blocker plates 470, 471 may be located (e.g., vertically aligned with) at or near the central axis 203 of the substrate 202 and substrate support 206, may be located (e.g., vertically aligned with) at or near an edge of the substrate 202 and substrate support 206, or anywhere therebetween.

The blocker plates 470, 471 are substantially flat plates and are positional. In one or more embodiments, the blocker plates 470, 471 include a cooling system (e.g., a heat sink) for improved heat absorbing and/or reflection. In one or more embodiments, the blocker plates 470, 471 are pivotable about the respective center thereof. The blocker plates 470, 471 are pivotable between a position where the blocker plates 470, 471 are parallel to the substrate 202 and a position where the blocker plates 470, 471 are nonparallel to, or perpendicular to, the substrate 202. In one or more embodiments, the blocker plates 470, 471 are made of a heat absorbing and/or reflecting material, such as, stainless steel, aluminum, titanium, silicone carbide, graphite coated with silicon carbide, and/or any metal or ceramic that has a relatively high melting temperature (e.g., greater than 1300° C.) and/or is relatively resistant for semiconductor environments. Other materials are contemplated. In one or more embodiments, the blocker plates 470, 471 have a heat absorbing and/or reflecting coating. In one or more embodiments, the blocker plates 470, 471 or a portion thereof, are opaque.

The blocker plates 470, 471 absorb and/or reflect heat transmitted from the heat sources 241, 243 thus creating a cooling profile in the shape of the blocker plates 470, 471. Accordingly, the temperature profile of the substrate 202 may be modified by the blocker plates 470, 471.

The blocker plates 470, 471 may be pivoted to control the cooling profile (e.g., the amount and shape of heat absorbed and/or reflected by the blocker plates 470, 471). For instance, when the blocker plates 470, 471 are parallel to the substrate 202, the blocker plates 470, 471 absorb or reflect a maximum amount of heat for the given shape of the blocker plate 470, 471 by exposing the maximum amount of surface area to the one heat sources 241, 243. When the blocker plates 470, 471 are nonparallel to the substrate 202, the blocker plates 470, 471 absorb and/or reflect less heat by exposing a smaller amount of surface area to the one or more heat sources 241, 243. For example, the blocker plates 470, 471 can absorb and/or reflect a minimum amount of heat for the given shape of the blocker plate 470, 471, such as absorbing and/or reflecting about no heat. In one or more embodiments, the blocker plates 470, 471 may be pivoted 360 degrees about the pivot point and may be positioned in any position within the 360-degree range for maximum controllability of heat absorption and/or reflection. In one more embodiments, the blocker plates 470,471 can be pivoted within an angular range of 0 degrees to 180 degrees, such as 0 degrees to 90 degrees. In one or more embodiments, the blocker plates 470,471 may include a different material and/or coating on a first side 475 relative to a second side 476 and, therefore, when the blocker plates 470, 471 are flipped 180 degrees, the blocker plates 470, 471 may include different absorption and/or reflection properties. In such an embodiment, the blocker plates 470, 471 can be positioned vertically at a 0 degree angle, the first side can be exposed to energy at the position of a +90 degree angle, and the second side can be exposed to energy at the position of a −90 degree angle. The blocker plates 470, 471 may be pivoted by one or more actuators 474 of the cooling system 143 that may simultaneously or independently pivot each blocker plate 470, 471. The present disclosure contemplates that the heat described herein can be IR energy, ultraviolet (UV energy), or other forms of energy. The blocker plate 470, 471 position can be dynamically controlled by the one or more actuators 474 to facilitate different heat profiles during processing of the substrate 202.

Similarly, the shape of the blocker plates 470, 471, in part, determines the portion of the heat absorbed and/or reflected. Thus, the shape of the blocker plates 470, 471 determines the cooling profile. The blocker plates 470, 471 may be any shape and size so long as the blocker plates 470, 471 are positioned within the chamber 110 in a way to absorb and/or reflect at least a portion of the heat from the heat sources 241, 243 corresponding to the areas of temperature non-uniformity. The shape and/or size of the blocker plates 470, 471 can be altered to facilitate a target temperature profile. For example, as illustrated in FIG. 4A, the blocker plates 470, 471 may be circular plates. In one or more embodiments, the blocker plates 470, 471 may also include openings 473 (e.g., holes—shown in ghost in FIG. 4A) of any shape so as to allow for some heat to pass through the blocker plates 470, 471 depending on the temperature non-uniformity. The present disclosure also contemplates that the openings 473 can be filled in with material (such as transparent quartz, for example).

While the presently illustrated implementation includes one upper blocker plate 470 and two lower blocker plates 471, it is understood that there may be any number of blocker plates 470, 471 which may be upper blocker plates 470 or which may be lower blocker plates 471. In one or more embodiments, the upper blocker plates 470 are omitted, and in one or more embodiments the lower blocker plates 471 are omitted.

FIG. 4B illustrates a schematic top view of a substrate 402 with a non-uniform temperature profile. In the embodiment illustrated in FIG. 4B, the temperature of the center 493 of the substrate 402 is higher than the temperature at the perimeter 492. FIG. 4C illustrates a schematic top view of one of the blocker plates 470, 471 of FIG. 4A that may be used to generate a cooling profile complementary to the non-uniform temperature profile of the substrate 402 of FIG. 4B to make the resulting temperature profile uniform. FIG. 4D includes a chart 494 illustrating the non-uniform temperature profile 497 of the substrate 402 of FIG. 4B, a chart 495 illustrating the cooling profile 498 generated by the blocker plate 470, 471 of FIG. 4C, and chart 496 illustrates the resulting temperature profile 499 of the substrate 402 of FIG. 4B due to the use of the blocker plate 470, 471 of FIG. 4C.

As shown in chart 494 of FIG. 4D, the substrate 402 may have a temperature profile 497 with a higher temperature at the center 493 of the substrate 402 than the temperature at the perimeter 492 of the substrate 402. As shown in chart 495 of FIG. 4D, the blocker plate 470, 471 of FIG. 4C may be designed (e.g., through the manipulation of the shape of the blocker plate and the position of the blocker plate) to have a complementary temperature profile 498 to the non-uniform temperature profile of the substrate 202 of FIG. 4B (e.g., a cooling profile 498). As shown in chart 496 of FIG. 4D, the cooling profile 498 of the blocker plate 470, 471 may be used to make the resulting temperature profile 499 of the substrate 402 uniform.

While FIGS. 2A-4D illustrate particular temperature profiles and particularly shaped cooling channels and plates in particular positions, it is understood that the temperature profiles may vary across the entirety of a substrate in non-uniform patterns and the shapes and positions of the cooling channels and blocker plates may vary accordingly.

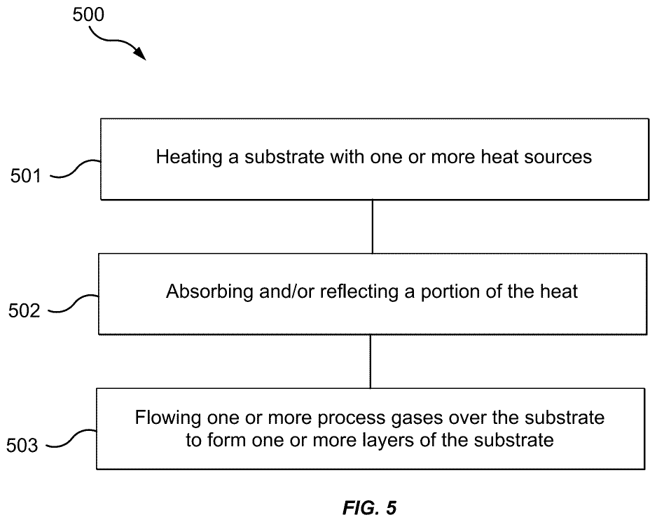

FIG. 5 illustrates a method 500 of substrate processing for semiconductor processing. Specifically, method 500 is a method for modifying a temperature profile of a substrate (such as substrate 202 of FIGS. 2A-2B, 3A-3B, and 4A-4B).

At operation 501, the substrate is heated while in the processing volume (such as processing volume 236 of FIGS. 2A, 3A, and 4A) of a chamber (such as chamber 110 of FIGS. 2A, 3A, and 4A) with one or more heat sources (such as heat sources 241, 243 of FIGS. 2A, 3A, and 4A) generating heat.

At operation 502, a portion of the heat is absorbed and/or reflected to reduce the heat supplied to a portion of the substrate.

In one or more embodiments, absorbing and/or reflecting the portion of the heat includes flowing an heat absorbing fluid through one or more cooling channels (such as cooling channels 270, 271, 370, 371 of FIGS. 2A, 2C, 3A, and 3C). In one or more embodiments, the one or more cooling channels are circular (such as illustrated and described with respect to FIGS. 2A and 2C). In one or more embodiments, the one or more cooling channels are U-shaped (such as illustrated and described with respect to FIGS. 3A and 3C). In one or more embodiments, the heat absorbing fluid is water vapor. In one or more embodiments, the heat absorbing fluid is water vapor or other fluid vapors (e.g. oils, alcohols, and/or solvents) including additional components such as one or more of carbon dioxide gas, silicon nitride nanoparticles, slurries (e.g., silicone based slurries), or molecular dye.

In one or more embodiments, absorbing and/or reflecting the portion of the heat includes absorbing and/or reflecting the portion of the heat with one or more blocker plates (such as blocker plates 470, 471 of FIGS. 4A and 4C). In one or more embodiments, absorbing the portion of the heat with the one or more blocker plates includes pivoting the one or more blocker plates from a first position where the one or more blocker plates are parallel to the substrate to a second position where the one or more blocker plates are perpendicular to the substrate. In one or more embodiments, the one or more blocker plates may be pivoted to a third, intermediate, position angularly between the first position and the second position.

In one or more embodiments, absorbing and/or reflecting the portion of the heat to reduce the heat supplied to the portion of the substrate includes determining the portion of the substrate is above a desired temperature or desired temperature threshold and, based on determining the portion is above a desired temperature or desired temperature threshold, absorbing and/or reflecting the portion of the heat to reduce the temperature of that portion. That is, the method 500 may include determining a temperature profile of the substrate, determining the temperature profile is non-uniform with respect to certain portions of the substrate, and modifying the temperature profile with one or more of the above-described embodiments for absorbing and/or reflecting heat. In one or more embodiments, the determining and temperature profile modification may be done in real time. For instance, the blocker plates may be dynamically pivoted to modify the temperature profile in real-time. In one or more embodiments, the non-uniformity of the temperature profile of the substrate may be known from previous substrate processing and the modification of the temperature profile may be preemptive.

At operation 503, one or more process gases (such as process gasses P1 of FIGS. 2A, 3A, and 4A) to form one or more layers of a substrate. The uniformity of the resulting temperature profile allows for higher uniformity in the one or more layers.

The present disclosure contemplates that one or more operations of the method 500 can be used in relation to processing other than deposition (such as substrate etching, chamber cleaning, and/or substrate cleaning). For example, operation 503 can include flowing one or more process gases over the substrate to clean the substrate and/or to etch the substrate. As another example, the substrate can be removed from the process chamber, and operation 503 can include flowing one or more process gases to clean the process chamber.

Benefits of the present disclosure include more heating and more uniform processing (such as layer formation on substrates); increased throughput; and enhanced device performance. It is contemplated that one or more portions of the subject matter disclosed herein may be combined. As an example, one or more aspects, features, components, operations, and/or properties of the various implementations of the processing system 100s illustrated in FIGS. 1, 2A, 3A, and 4A, the cooling channels 270, 271, the cooling channels 370, 371, the blocker plates 470, 471, and/or the method 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing system applicable for use in semiconductor manufacturing, comprising:
a chamber, comprising:
a chamber body at least partially defining an internal volume;
one or more windows disposed in the internal volume;
a substrate support at least partially disposed in the internal volume;
one or more heat sources operable to heat the internal volume; and
one or more cooling channels extending at least partially between the one or more heat sources and the one or more windows, the one or more cooling channels operable to flow a cooling fluid.

2. The processing system of claim 1, wherein the one or more cooling channels are part of one or more tubular loops.

3. The processing system of claim 2, wherein the one or more tubular loops are circular and a central axis of the one or more tubular loops is coaxial or parallel with a central axis of the substrate support.

4. The processing system of claim 2, wherein the one or more tubular loops are U-shaped with an inlet section and an outlet section connected by a curved section, and wherein the inlet section and the outlet section are parallel to a central axis of the substrate support.

5. The processing system of claim 1, further comprising:
a supply line configured to supply the cooling fluid to the one or more cooling channels;
a return line configured to receive the cooling fluid from the one or more cooling channels;
a flow controller, wherein the flow controller is configured to supply the supply line with the cooling fluid; and
a control system is configured to control the flow controller to supply the supply line with the fluid.

6. A processing system applicable for use in semiconductor manufacturing, comprising:
a chamber, comprising:
a chamber body at least partially defining an internal volume;
a substrate support at least partially disposed in the internal volume;
one or more heat sources operable to heat the internal volume; and
one or more blocker plates disposed between the one or more heat sources and the substrate support.

7. The processing system of claim 6, wherein the one or more blocker plates are pivotable between a first position and a second position, and in the first position a larger surface area of the one or more blocker plates is exposed to the one or more heat sources than in the second position.

8. The processing system of claim 7, wherein the surface area of the one or more blocker plates is part of one or more opaque surfaces of the one or more blocker plates.

9. The processing system of claim 6, wherein the one or more blocker plates are pivotable between a first position and a second position, the one or more blocker plates are parallel to a top surface of the substrate support in the first position, and the one or more blocker plates are nonparallel to the top surface of the substrate in the second position.

10. The processing system of claim 9, further comprising one or more actuators coupled to the one or more blocker plate, wherein the one or more actuators are configured to dynamically pivot the one or more blocker plates between the first position and the second position to modify a surface area of the one or more blocker plates exposed to the one or more heat sources.

11. The processing system of claim 9, wherein the one or more blocker plates is pivotable to a third position, wherein the third position is angularly between the first position and the second position.

12. The processing system of claim 10, wherein a first side of the one or more blocker plates includes a first material, and wherein a second side of the one or more blocker plates includes a second material.

13. A method of substrate processing for semiconductor processing, comprising:
heating a substrate positioned in a processing volume of a chamber using one or more heat sources;
absorbing and/or reflecting a portion of the heat to reduce the heat supplied to a portion of the substrate; and
flowing one or more processing gases over the substrate to form one or more layers of the substrate.

14. The method of claim 13, wherein the absorbing and/or reflecting the portion of the heat comprises flowing a fluid through one or more cooling channels extending at least partially between the substrate and the one or more heat sources, wherein the fluid is infrared (IR) absorbing.

15. The method of claim 14, wherein the one or more cooling channels are circular and a central axis of the one or more cooling channels is coaxial or parallel a central axis of the substrate.

16. The method of claim 14, wherein the one or more cooling channels are U-shaped with an inlet section and an outlet section connected by a curved section, and wherein the inlet section and the outlet section are parallel to a central axis of the substrate.

17. The method of claim 14, wherein the fluid comprises one or more of water vapor, carbon dioxide gas, silicon nitride nanoparticles, silicon based slurries or molecular dye.

18. The method of claim 13, wherein the absorbing and/or reflecting the portion of the heat comprises positioning one or more blocker plates to absorb the portion of the heat.

19. The method of claim 18, wherein the positioning comprises pivoting the one or more blocker plates from a first position to a second position, the one or more blocker plates are parallel to a top surface of the substrate in the first position, and the one or more blocker plates are nonparallel to the top surface of the substrate in the second position.

20. The method of claim 13, further comprising:
determining the portion of the substrate is above a temperature threshold, wherein the absorbing and/or reflecting the portion of the heat is conducted in response to the determination that the portion of the substrate is above the temperature threshold.
